(19) United States
(12) Patent Application Publication
(10) Pub. No.: US 2009/0261914 A1
(43) Pub. Date: Oct. 22, 2009

(54) CRYSTAL OSCILLATOR CIRCUITS

(75) Inventors: Hueh-Wu Kao, Hsinchu Hsien (TW); Pi-Fen Chen, Hsinchu City (TW); Wen-Chin Hsieh, Hsinchu City (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: MEDIATEK INC., Hsin-Chu (TW)

(21) Appl. No.: 12/104,530

(22) Filed: Apr. 17, 2008

(51) Int. Cl. H03B 5/32

(52) U.S. Cl. 331/158

(57) ABSTRACT

An oscillator circuit. A gain stage element is coupled between both terminals of the crystal. The gain stage element provides a transconductance for oscillation according to a current provided by a current source, and outputs a periodic signal through an output terminal. A bias element is coupled between an input terminal and the output terminal of the gain stage element to bias the gain stage element. A first capacitor is coupled to the input terminal of the gain stage element. A second capacitor is coupled to the output terminal of the gain stage element. A controller detects the periodic signal, and adjusts the current when the periodic signal is obtained.

### BACKGROUND OF THE INVENTION

1. Field of the Invention

The invention relates to oscillator circuits, and more particularly to circuits for starting control of crystal oscillator circuits.

2. Description of the Related Art

FIG. 1 illustrates a conventional crystal oscillator circuit 10. Gain stage element 12 provides the transconductance according to the current provided by current source 14 required for oscillation. Crystal Xtal, which is a high-Q resonator, is connected between input terminal XIN and output terminal XOUT of gain stage element 12. In addition, both terminals of crystal Xtal are connected to the ground level through capacitors C1 and C2, respectively. Bias element Rf, connected between input terminal XIN and output terminal XOUT of gain stage element 12, is required to bias gain stage element 12 since the resonator is essentially equivalent to an open circuit at DC. Buffer 16 is connected to terminal XOUT of gain stage element 12, and amplifies signal levels thereon to generate a full swing clock. Gain stage element 12, bias element Rf, crystal Xtal, and capacitors C1 and C2 forms an oscillation loop. Here, gain stage element 12, current source 14, buffer 16 and bias element Rf are usually internal elements formed on a chip. Crystal Xtal and capacitors C1 and C2 are external elements outside the chip.

According to Barkhausen Criteria, two basic conditions are required for oscillation of the crystal oscillator circuit 10. One is a phase shift around the oscillator loop of n*360° degree (n is an integer), and another is an open loop gain thereon greater than 1. Gain stage element 12 provides approximately 180° phase shift from its input terminal XIN and output terminal XOUT. The network formed by crystal Xtal, bias element Rf, and capacitors C1 and C2 provide the additional 180° phase shift. Therefore, an n*360° phase shift around the oscillator loop is obtained. If the magnitude of the open loop gain is greater than 1 and the total phase shift is 360°, the oscillation of the crystal oscillator circuit 10 is achieved.

Conventional crystal oscillator circuits may suffer from long start-up time or lack of precision of frequency. It is difficult to achieve both requirements (short start-up time and precise oscillation frequency). Thus, there is a need for an approach to reducing the start-up time of a quartz-crystal oscillator circuit and obtaining a precise oscillation frequency.

### BRIEF SUMMARY OF INVENTION

Oscillator circuits are provided. An exemplary embodiment of an oscillator circuit comprises a crystal, a gain stage element coupled between both terminals of the crystal, the gain stage element providing a transconductance for oscillation according to a current provided by a current source, and outputting a periodic signal through an output terminal, a bias element coupled between an input terminal and the output terminal of the gain stage element to bias the gain stage element, a first capacitor network comprising a first switch and a first capacitor coupled to the input terminal of the gain stage element, and a second switch and a second capacitor coupled to the input terminal of the gain stage element, a second capacitor network comprising a third switch and a third capacitor coupled to the output terminal of the gain stage element, and a fourth switch and a fourth capacitor coupled to the output terminal of the gain stage element, and a controller selectively switching the first switch, the second switch, the third switch, and the fourth switch according to the periodic signal.

Another exemplary embodiment of an oscillator circuit comprises a crystal, a gain stage element coupled between both terminals of the crystal, the gain stage element providing a transconductance for oscillation according to a current provided by a current source, and outputting a periodic signal through an output terminal, a bias element coupled between an input terminal and the output terminal of the gain stage element to bias the gain stage element, a first capacitor coupled to the input terminal of the gain stage element, a second capacitor coupled to the output terminal of the gain stage element, and a controller detecting the periodic signal, and adjusting the current when the periodic signal is obtained.

Another exemplary embodiment of an oscillator circuit comprises a crystal, a gain stage element coupled between both terminals of the crystal, the gain stage element providing a transconductance for oscillation according to a current provided by a current source, and outputting a periodic signal through an output terminal, a bias element coupled between an input terminal and the output terminal of the gain stage element to bias the gain stage element, a first capacitor coupled to the input terminal of the gain stage element, a second capacitor coupled to the output terminal of the gain stage element, a first switch and a third capacitor coupled to the input terminal of the gain stage element, a second switch and a fourth capacitor coupled to the output terminal of the gain stage element, and a controller detecting the periodic signal, turning on the first switch and the second switch and adjusting the current when the periodic signal is obtained.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 illustrates a conventional crystal oscillator circuit; and

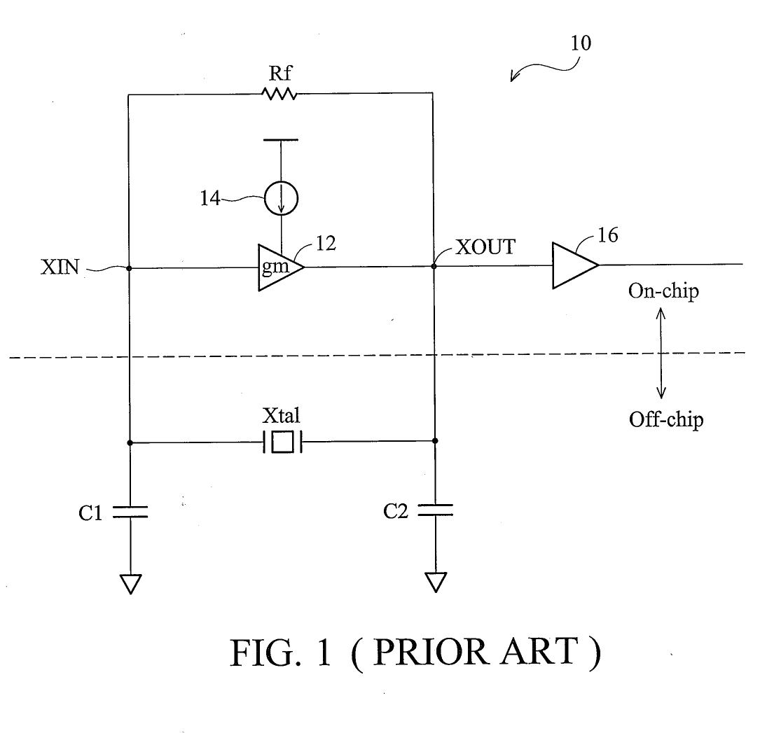

FIG. 2A illustrates a crystal oscillator circuit according to an embodiment of the invention.

FIG. 2B illustrates a crystal oscillator circuit according to another embodiment of the invention.

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims.

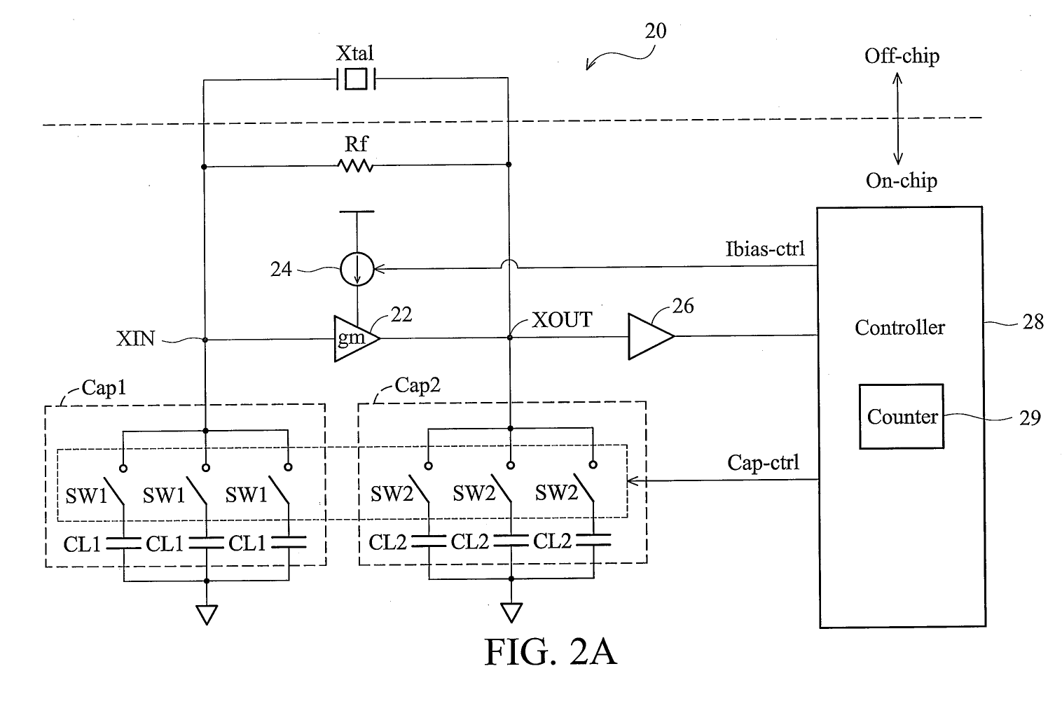

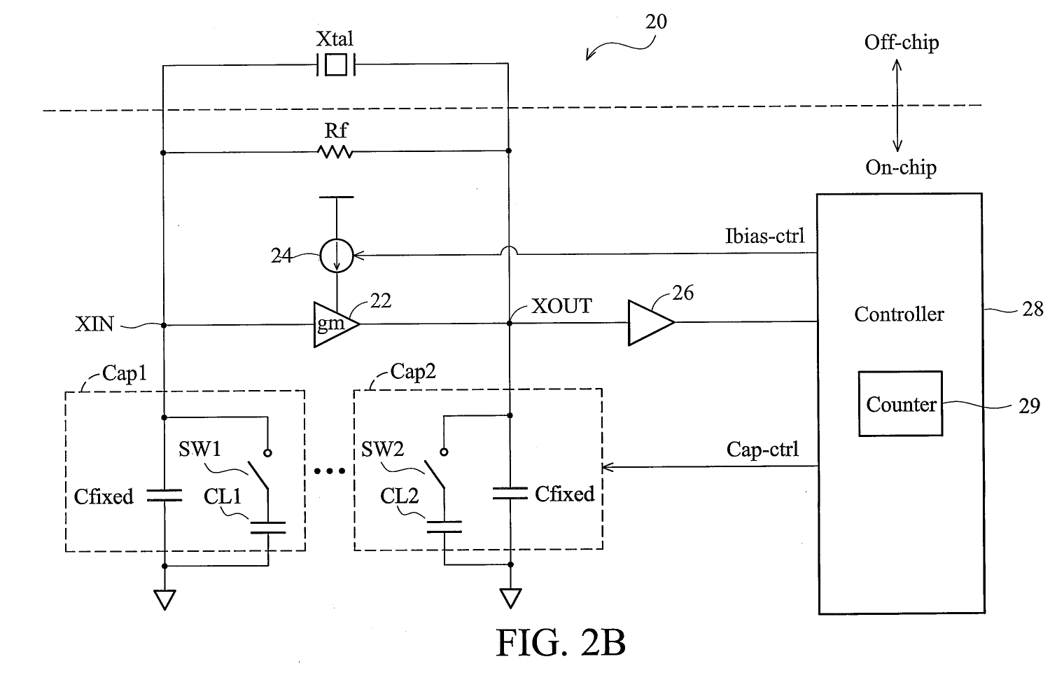

FIG. 2A illustrates a crystal oscillator circuit 20 according to an embodiment of the invention. Gain stage element 22 provides the transconductance according to the current provided by current source 24 required for oscillation. Crystal Xtal, which is a high-Q resonator, is connected between input terminal XIN and output terminal XOUT of gain stage element 22. Bias element Rf, connected between input terminal XIN and output terminal XOUT of gain stage element 22, is required to bias gain stage element 22 since the resonator is essentially equivalent to an open circuit at DC. In an embodiment, the bias element can be a resistor. Buffer 26 is connected to terminal XOUT of gain stage element 22, and amplifies signal levels thereon to generate a full swing clock. The buffer 26 can be implemented by an amplifier, an inverter, or an analog-to-digital converter. The purpose of the buffer 26 is to provide the next stage with proper signal swing.

Capacitor network Cap1 is connected between input terminal XIN of gain stage element 22 and the ground level, and capacitor network Cap2 is connected between output terminal XOUT of gain stage element 22 and the ground level. Capacitor network Cap1 comprises switches SW1 and capacitors CL1, each connected in serial between input terminal XIN of gain stage element 22 and the ground level. Capacitor network Cap2 comprises switches SW2 and capacitors CL2, each connected in serial between output terminal XOUT of gain stage element 22 and the ground level. In an embodiment, capacitor networks Cap1 and Cap2 can be implemented inside the chip for easy adjustment by controller 28.

Gain stage element 22 outputs periodic signals through output terminal XOUT when oscillation of crystal oscillator circuit 20 is activated. Controller 28 detects the oscillation status of crystal oscillator circuit 20 and outputs bias control signal Ibias-ctrl to control loop gain and capacitance control signal Cap-ctrl to control equivalent capacitance of the circuit. The oscillation status of crystal oscillator circuit 20 is obtained by controller 28 according to the periodic signal received from buffer 26. To ensure the oscillation of crystal oscillator circuit 20, controller 28 outputs bias control signal Ibias-ctrl and capacitance control signal Cap-ctrl when a voltage level of the periodic signal exceeds a predetermined level for a predetermined times in a predetermined period. Specifically, controller 28 may comprise a counter 29 triggered by the periodic signal, and the periodic signal is confirmed when a count value of the counter exceeds a predetermined value.

According to the invention, some of switches SW1 and SW2 are turned off initially, thus the equivalent capacitance of the circuit is low to decrease the start-up period required for activation oscillation. As the oscillation of crystal oscillator circuit 20 is confirmed by controller 28, the equivalent capacitance of the circuit can be increased to obtain more accurate oscillation frequency, 32768 Hz as an example. Thus, controller 28 outputs capacitance control signal Cap-ctrl to turn on the initially turned-off switches to increase the equivalent capacitance of the circuit.

FIG. 2B shows a crystal oscillator circuit 20 according to one embodiment of the invention. The capacitor network Cap1 comprises a fixed capacitor C_{fixed1}, a switch SW1, and a capacitor CL1. The capacitor network Cap2 comprises a fixed capacitor C_{fixed2}, a switch SW2, and a capacitor CL2. The fixed capacitors C_{fixed1} and C_{fixed2} are used to provide an initial capacitance value since there are no switches connected there to. Once the oscillation status is confirmed by the controller 28, the capacitor networks Cap1 and Cap2 can be switched to provide a larger capacitance value. There could be a plurality of capacitors CL1 and CL2 in this embodiment. The bias element Rf shown in FIG. 2A or FIG. 2B can be implemented within or outside the chip.

Lower capacitance value and higher gain of the gain stage element 22 can help to achieve a shorter start-up time. However, for saving power, the gain of the gain stage element 22 may initially be set to a lower value as long as the start-up time is acceptable. Once the equivalent capacitance of the circuit is changed, the gain of the gain element 22 can be adjusted by current source 24 to maintain the oscillation of crystal oscillator circuit 20.

While the invention has been described by way of example and in terms of preferred embodiment, it is to be understood that the invention is not limited thereto. Those who are skilled in this technology can still make various alterations and modifications without departing from the scope and spirit of this invention. Therefore, the scope of the present invention shall be defined and protected by the following claims and their equivalents.

What is claimed is:

1. An oscillator circuit, comprising:
a crystal;
a gain stage element coupled between both terminals of the crystal, the gain stage element providing a transconductance for oscillation according to a current provided by a current source, and outputting a periodic signal through an output terminal;
a bias element coupled between an input terminal and the output terminal of the gain stage element to bias the gain stage element;
a first capacitor network comprising a first switch and a first capacitor coupled to the input terminal of the gain stage element, and a second switch and a second capacitor coupled to the input terminal of the gain stage element;
a second capacitor network comprising a third switch and a third capacitor coupled to the output terminal of the gain stage element, and a fourth switch and a fourth capacitor coupled to the output terminal of the gain stage element; and
a controller selectively switching the first switch, the second switch, the third switch, and the fourth switch according to the periodic signal.

2. The oscillator circuit as claimed in claim 1, wherein the bias element is a resistor.

3. The oscillator circuit as claimed in claim 1, further comprising a buffer coupled between the gain stage element and the controller for amplifying the periodic signal.

4. The oscillator circuit as claimed in claim 1, wherein the first switch and the third switch are turned on, and the second switch and the fourth switch are turned off before the periodic signal is obtained by the controller.

5. The oscillator circuit as claimed in claim 4, wherein the controller turns on the first switch and the third switch when the periodic signal is obtained.

6. The oscillator circuit as claimed in claim 1, wherein the controller adjusts the current when the periodic signal is obtained.

7. The oscillator circuit as claimed in claim 1, wherein the periodic signal is obtained when a voltage level of the periodic signal exceeds a predetermined level for a predetermined time.

8. The oscillator circuit as claimed in claim 1, wherein the periodic signal is obtained when a voltage level of the periodic signal exceeds a predetermined level for a predetermined time in a predetermined period.

9. The oscillator circuit as claimed in claim 1, wherein the controller comprises a counter triggered by the periodic signal, and the periodic signal is obtained when a count value of the counter exceeds a predetermined value.

10. An oscillator circuit, comprising:
a crystal;
a gain stage element coupled between both terminals of the crystal, the gain stage element providing a transconductance for oscillation according to a current provided by a current source, and outputting a periodic signal through an output terminal;
a bias element coupled between an input terminal and the output terminal of the gain stage element to bias the gain stage element;
a first capacitor coupled to the input terminal of the gain stage element;
a second capacitor coupled to the output terminal of the gain stage element; and
a controller detecting the periodic signal, and adjusting the current when the periodic signal is obtained.

11. The oscillator circuit as claimed in claim 10, wherein the bias element is a resistor.

12. The oscillator circuit as claimed in claim 10, further comprising a buffer coupled between the gain stage element and the controller for amplifying the periodic signal.

13. The oscillator circuit as claimed in claim 10, wherein the periodic signal is obtained when a voltage level of the periodic signal exceeds a predetermined level for a predetermined time.

14. The oscillator circuit as claimed in claim 10, wherein the periodic signal is obtained when a voltage level of the periodic signal exceeds a predetermined level for a predetermined time in a predetermined period.

15. The oscillator circuit as claimed in claim 10, wherein the controller comprises a counter triggered by the periodic signal, and the periodic signal is obtained when a count value of the counter exceeds a predetermined value.

16. The oscillator circuit as claimed in claim 10, further comprising a first switch and a third capacitor coupled to the input terminal of the gain stage element, and a second switch and a fourth capacitor coupled to the output terminal of the gain stage element.

17. The oscillator circuit as claimed in claim 16, wherein the controller turns off the first switch and the second switch when the periodic signal is obtained.

18. An oscillator circuit, comprising:
a crystal;
a gain stage element coupled between both terminals of the crystal, the gain stage element providing a transconductance for oscillation according to a current provided by a current source, and outputting a periodic signal through an output terminal;
a bias element coupled between an input terminal and the output terminal of the gain stage element to bias the gain stage element;
a first capacitor coupled to the input terminal of the gain stage element;
a second capacitor coupled to the output terminal of the gain stage element;
a first switch and a third capacitor coupled to the input terminal of the gain stage element;
a second switch and a fourth capacitor coupled to the output terminal of the gain stage element; and
a controller detecting the periodic signal, turning on the first switch and the second switch and adjusting the current when the periodic signal is obtained.

19. The oscillator circuit as claimed in claim 18, wherein the bias element is a resistor.

20. The oscillator circuit as claimed in claim 18, further comprising a buffer coupled between the gain stage element and the controller for amplifying the periodic signal.

21. The oscillator circuit as claimed in claim 18, wherein the periodic signal is obtained when a voltage level of the periodic signal exceeds a predetermined level for a predetermined time.

22. The oscillator circuit as claimed in claim 18, wherein the periodic signal is obtained when a voltage level of the periodic signal exceeds a predetermined level for a predetermined time in a predetermined period.

23. The oscillator circuit as claimed in claim 18, wherein the controller comprises a counter triggered by the periodic signal, and the periodic signal is obtained when a count value of the counter exceeds a predetermined value.

24. The oscillator circuit as claimed in claim 23, wherein the controller turns on the first switch and the second switch when the periodic signal is obtained.
